(19) United States
(12) Patent Application Publication
(10) Pub. No.: US 2009/0279288 A1
(43) Pub. Date: Nov. 12, 2009

(54) LIGHT EMITTING MODULE WITH SOLAR CELL UNIT

(75) Inventor: GA-LANE CHEN, Santa Clara, CA (US)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/434,663

(22) Filed: May 3, 2009

(30) Foreign Application Priority Data
May 6, 2008 (CN) 200810301433.5

(51) Int. Cl. F21L 4/00; H01L 31/12

(52) U.S. Cl. 362/183; 257/84; 257/E31.095

(57) ABSTRACT

In one exemplary embodiment, a light emitting module includes a LED chip, a solar cell unit, and an interconnecting electrode. The LED chip includes a first P type semiconductor layer. The solar cell unit includes a second P type semiconductor layer. The interconnecting electrode is sandwiched between the first and second P type semiconductor layers. The interconnecting electrode electrically couples the solar cell unit to the LED chip.

### BACKGROUND

1. Technical Field

The present invention relates to a light emitting module, and particularly to a light emitting module with a solar cell unit.

2. Description of Related Art

Nowadays, for purpose of energy-saving and environment protecting, more and more green energy techniques such as wind power, tidal power, and solar energy are developed. However, wind power generators and tidal power generators can only applied in specific areas. Thus, a complex energy distributing system is required for distributing energy generated by wind power generators and tidal power generators. In contrast, solar panels can be installed in any place under sunlight. Thus, solar panels and energy consuming devices can be installed in a same place to construct energy-independent systems separated from exterior power supply system. For example, a light emitting diode (LED) road lamp can be electrically connected to a solar panel. The solar panel stores electrical energy during day time and supply electrical power to the LED road lamp when necessary. To establish an electrical connection between LED road lamps and solar panels, usually, additional connecting means (for example, printed circuit boards) are required. However, the connecting means increase volume, complexity, and manufacturing cost of the system.

Therefore, there is a desire to develop a compact energy-independent system, such as a light emitting module.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of embodiments. Moreover, in the drawings, like reference numerals designate corresponding parts throughout the different views.

FIG. 1 is a cross-sectional view of a light emitting module in accordance with a first embodiment.

FIG. 2 is a cross-sectional view of a light emitting module in accordance with a second embodiment.

### DETAILED DESCRIPTION

The present light emitting module will be described in detail accompanying with following embodiments.

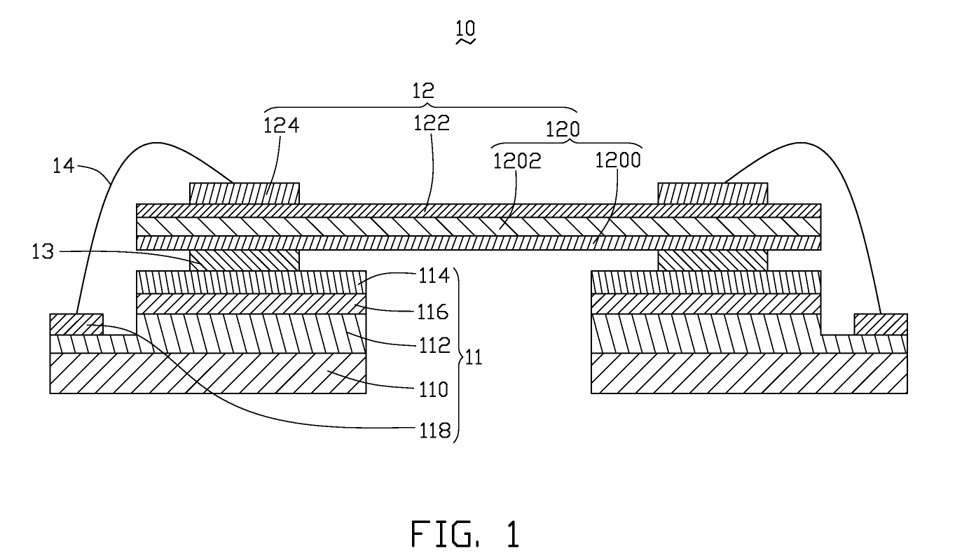

Referring to FIG. 1, a light emitting module 10 according a first embodiment includes a light emitting diode (LED) chip 11, a solar cell unit 12, and an interconnecting electrode 13 electrically coupling the light emitting module 10 to the solar cell unit 12.

The LED chip 11 includes a first N type semiconductor layer 112, a first P type semiconductor layer 114, a quantum well layer 116 sandwiched between the first N type semiconductor layer 112 and the first P type semiconductor layer 114, and an N type electrode 118 formed on the first N type semiconductor layer 112.

The first N type semiconductor layer 112 is comprised of Silicon-doped gallium nitride (GaN), and the first P type semiconductor layer 114 is comprised of magnesium-doped aluminum gallium nitride (AlGaN). The N type electrode 118 can be formed on the first N type semiconductor layer 112 using a deposition etching process.

The LED chip 11 further includes a transparent substrate 110. The first N type semiconductor layer 112, the quantum well layer 116 and the first P type semiconductor layer 114 can be formed on the transparent substrate 110 in the order written. The transparent substrate 110 can be comprised of sapphire or indium-tin oxide doped sapphire.

The solar cell unit 12 includes a photovoltaic PN junction 120, a transparent conductive layer 122, and a front electrode layer 124. The photovoltaic PN junction 120 includes a second P type semiconductor layer 1200 and a second N type semiconductor layer 1202 in contact with the second P type semiconductor layer 1200. In the present embodiment, the second N type semiconductor layer 1202 is a N type hydrogenated amorphous silicon layer deposited using a chemical vapor deposition (CVD) method, and the second P type semiconductor layer 1200 is a P type hydrogenated amorphous silicon layer deposited using a CVD method. In other words, the solar cell unit 12 is an amorphous silicon solar cell.

The transparent conductive layer 122 is formed on the second N type semiconductor layer 1202, and can be comprised of indium tin oxide (ITO) or zinc oxide (ZnO). The transparent conductive layer 122 is configured to establish an electrical connection to the solar cell unit 120 and protect the solar cell unit 120 from being damaged.

The front electrode 124 is formed on the transparent conductive layer 122, and can be comprised of silver (Ag), copper (Cu), molybdenum (Mo), aluminum (Al), Cu—Al alloy, Ag—Cu alloy, or Cu—Mo alloy. In addition, the front electrode 124 is electrically connected to the N type electrode 118 by an electrical wire 14.

The interconnecting electrode 13 is sandwiched between the photovoltaic PN junction 120 and the first P type semiconductor layer 114 of the LED chip 11, and is configured for electrically coupling the solar cell unit 12 to the LED chip 11. The interconnecting electrode 13 can also be comprised of silver (Ag), copper (Cu), molybdenum (Mo), aluminum (Al), Cu—Al alloy, Ag—Cu alloy, or Cu—Mo alloy.

When light (for example, sunlight) is incident onto the solar cell unit 12, holes and electrons in the photovoltaic PN junction 120 are respectively attracted by the second P type semiconductor layer 1200 and the second N type semiconductor 1202 to move and accumulated at two ends of the second P type semiconductor layer 1200 and the second N type semiconductor layer 1202. As such, an electrical potential difference between the second P type semiconductor layer 1200 and the second N type semiconductor layer 1202 is produced. Further, as discussed above, the second N type semiconductor layer 1202 is electrically connected to the first N type semiconductor layer 112 by the transparent conductive layer 122, the front electrode 124, the electrical wire 14, and the N type electrode 118, the second P type semiconductor layer 1200 is electrically connected to the first P type semiconductor layer 114 by the interconnecting electrode 13. Thus, an electrical potential difference also exists between the first P type semiconductor layer 114 and the first N type semiconductor layer 112 of the LED chip, which drives the holes in the first P type semiconductor layer 114 move to the first N type semiconductor layer 112, and the electrons in the first N type semiconductor layer 112 move to the first P type semiconductor layer 114. Light will be emitted out when the holes meet the electrons. Plainly, the solar cell unit 12 receives sunlight, converts solar energy into electrical energy, and supplies the electrical energy to the LED chip 11. It is understood that in the energy converting process, the interconnecting electrode 13 both serves as a P type electrode of the LED chip 11 and a back electrode of the solar cell unit 12. As such, compared with a traditional assembly of separated LED chip and solar cell unit, a manufacturing process of the present light emitting module 10 is simplified and a manufacturing cost of the light emitting module is also decreased. In addition, the light emitting module can also be more compact in volume and is very suitable for miniaturized applications such as serving as a backlight module of a mobile phone.

The number of the LED chip 11 is not limited to two as shown in FIG. 1, and may vary according to practical applications. The number of the interconnecting electrode 13 is the same to that of the LED chip 11 for corresponding electrically connecting the LED chip 11 to the solar cell unit 12.

Additionally, in the light emitting module 10, the arrangement of the first N type semiconductor layer 112 and the first P type semiconductor layer 114 can be interchanged together with interchanging the arrange of the second N type semiconductor layer 1202 and the second P type semiconductor layer 1200. As such, the interconnecting electrode 13 is sandwiched between the first N type semiconductor layer 112 and the second N type semiconductor layer 1202, and the solar cell unit 12 is also electrically coupled to the LED chip 11. In this condition, the solar cell unit 12 can also supply electrical power to the LED chip 11.

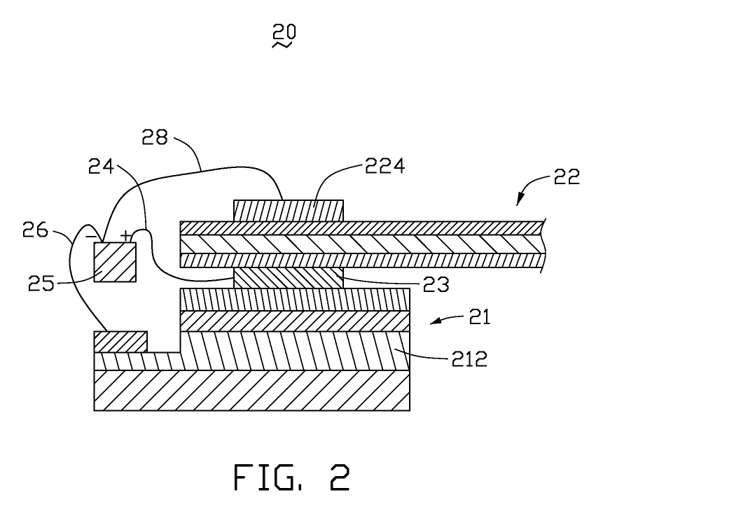

Referring to FIG. 2, a light emitting module 20 according to is similar to the light emitting module 10 except that further comprising a electrical-storing device 25. The solar cell unit 22 receives sun energy, convert it into electrical energy, and store the electrical energy in the electrical-storing device 25 in day time. The electrical-storing device 25 can supply power to the LED chip 21 in night. Examples of the electrical-storing device 25 include lead-acid battery, Li-ion battery, Ni—H battery, and supercapacitor.

The N type semiconductor layer 212 of the LED chip 21 and the front electrode 224 of the solar cell unit 22 are electrically connected to the negative electrode of the electrical-storing device 25 by the electrical wires 24, 26. The interconnecting electrode 23 is electrically connected to the positive electrode of the electrical-storing device 25 by the electrical wire 28. In operation, the solar cell unit 22 charges the electrical-storing device 25 through the electrical wires 24 and 28, and the recharge battery 25 supply power to the LED chip 21 through the electrical wires 26 and 28.

While certain embodiments have been described and exemplified above, various other embodiments will be apparent to those skilled in the art from the foregoing disclosure. The present invention is not limited to the particular embodiments described and exemplified but is capable of considerable variation and modification without departure from the scope of the appended claims.

What is claimed is:

1. A light emitting module comprising:
at least one LED chip, the at least one LED chip each comprising a first P type semiconductor layer;
a solar cell unit comprising a second P type semiconductor layer; and
at least one interconnecting electrode sandwiched between the first and second P type semiconductor layers, the interconnecting electrode electrically coupling the solar cell unit to the LED chip.

2. The light emitting module as claimed in claim 1, wherein, the at least one LED chip each comprises a first N type semiconductor layer and a N type electrode formed on the first N type semiconductor layer, and the solar cell unit comprises a front electrode formed on a side thereof opposite to the second P type semiconductor layer, the N type electrode being electrically connected to the front electrode.

3. The light emitting module as claimed in claim 2, wherein the N type electrode is electrically connected to the front electrode.

4. The light emitting module as claimed in claim 2, wherein the solar cell unit comprises a second N type semiconductor layer formed on a side thereof opposite to the second P type semiconductor layer, and a transparent conductive layer formed on the second N type semiconductor layer, the front electrode is formed on the transparent conductive layer.

5. The light emitting module as claimed in claim 2, further comprising a electrical-storing device electrically connected to the solar cell unit and the LED chip.

6. The light emitting module as claimed in claim 5, wherein the electrical-storing device comprises a positive electrode and a negative electrode, the first N type semiconductor layer of the LED chip and the front electrode of the solar cell unit are electrically connected to the negative electrode, and the interconnecting electrode is electrically connected to the positive electrode.

7. The light emitting module as claimed in claim 5, wherein the electrical-storing device is selected from the group consisting of lead-acid battery, Li-ion battery, Ni—H battery and supercapacitor.

8. The light emitting module as claimed in claim 2, wherein the front electrode is comprised of a material selected from the group consisting of Ag, Cu, Mo, Al, Cu—Al alloy, Ag—Cu alloy, and Cu—Mo alloy.

9. The light emitting module as claimed in claim 1, wherein the solar cell unit is an amorphous silicon solar cell.

10. A light emitting module, comprising:
at least one LED chip, each of the LED chip comprising a first N type semiconductor layer;
a solar cell unit comprising a second N type semiconductor layer; and
at least one interconnecting electrode sandwiched between the first and second N type semiconductor layers, the interconnecting electrode electrically coupling the solar cell unit to the LED chip.
